(19) United States
(12) Patent Application Publication
(10) Pub. No.: US 2005/0245032 A1
(43) Pub. Date: Nov. 3, 2005

(54) Application of a protective cover to an ophtalmological instrument part

(75) Inventor: Hartmut Kanngiesser, Zurich (CH)

Correspondence Address: OLIFF & BERRIDGE, PLC, P.O. BOX 19928, ALEXANDRIA, VA, 22320, US

(73) Assignee: SMT SWISS MICROTECHNOLOGY AG, Port (CH)

(21) Appl. No.: 11/090,200

(22) Filed: Mar. 28, 2005

Related U.S. Application Data
(60) Provisional application No. 60/566,449, filed on Apr. 30, 2004.

(30) Foreign Application Priority Data
Apr. 29, 2004 (EP) 04 405 265.2

(51) Int. Cl. H01L 21/8234

(52) U.S. Cl. 438/275

(57) ABSTRACT

An application system and an application method for applying a flexible protective cover (1) to the frustoconical tip (21) of an ophthalmological instrument part (2) are proposed. The protective cover (1) is arranged in the depression (31) of an applicator part (3) above a stamp (34) made of compressible material. The stamp (34) is attached to the base of the depression (31) and aligned towards the opening (32) of the depression (31). The tip (21) can be inserted into the protective cover (1) through the opening (32). During the inserting operation, a membrane (14) of the protective cover (1) comes into contact with the contact area (22) and is pressed against the stamp (34). The membrane (14) is pressed between the contact area (22) and the stamp (34) and air which is located between the membrane (14) and the contact area (22) is forced out. Moreover, an adhering region on the collar (11) of the protective cover (1) is pressed against the tip (21) and brings about an adherence of the protective cover (1) to the tip (21).

### TECHNICAL FIELD

The present invention relates to the application of a protective cover to an ophthalmological instrument part. The invention relates in particular to an application system which comprises a flexible protective cover for an instrument part with a tip tapering conically to a contact area to be placed on an eye and to an applicator part for applying the protective cover to the tip.

### PRIOR ART

In ophthalmology, instrument parts such as measuring heads, for example tonometers, or optical applicators, such as pachymeters, are often provided with a conically tapering, frustoconical tip, which has at the tapered end a contact area for placing on an eye. The frustoconical tip of these instrument parts on the one hand enables the attendant doctor or optician to have a better view of the eye to be treated or measured, on the other hand it facilitates the application of protective covers. When the eye is touched by the contact area of the instrument parts, it is possible for lacrimal fluid, and with it also pathogens, to be transferred from one patient to another. Moreover, germs or contaminants which adhere to the contact area can be introduced into the eye during the treatment or measurement. To avoid this, the instrument parts are correspondingly cleaned or provided with a clean protective cover which is as sterile as possible. Measurements on the eye, in particular eye-pressure measurements, are carried out very often. For example, eye-pressure measurements are performed on virtually every patient during eye examinations, the measurement generally taking a matter of just a few seconds. It should consequently also be possible for the preparation of the instrument parts, in particular their tips, for the measurement to be accomplished as quickly as possible. Otherwise, the attendant doctor or optician must have a number of instrument parts at his disposal, which he uses alternately.

### SUMMARY OF THE INVENTION

It is an object of the present invention to propose a novel application system and a novel method for applying a flexible protective cover to an instrument part which has a tip tapering conically to a contact area which can be placed on an eye. It is, in particular, an object of the present invention to propose an application system and an application method which permit rapid, reliable and reproducible application of a flexible protective cover to a conically tapering, substantially frustoconical, tip with a contact area for placing on an eye.

According to the present invention, these aims are achieved in particular by the elements of the independent claims. Further advantageous embodiments also emerge from the dependent claims and the description.

The application system comprises a flexible protective cover for an instrument part which has a tip tapering conically to a contact area which can be placed on an eye, and an applicator part for applying the protective cover to the tip.

The aforementioned aims are achieved by the present invention in particular by the applicator part having a depression with an opening and a base part, by a stamp made of compressible material being attached to the base part and aligned by the base part in the direction of the opening, by the protective cover being arranged above the stamp in the depression in such a way that it can be removed so that, to apply the protective cover, the tip can be inserted into the protective cover through the opening, a contact region of the protective cover that comes into contact with the contact area during the inserting operation being pressed between the contact area and the stamp and air which is located between the contact region of the protective cover and the contact area being forced out of the contact region. The forcing of air out of the region between the contact area and the contact region of the protective cover that comes into contact with the contact area has the advantage that measurements on the eye, for example measurements of the eye pressure, are not falsified by inclusions of air. In applications with optical applicators, the forcing out of the air has the advantage that rays of light are not refracted or diffused by inclusions of air.

The stamp preferably has a convex pressure-exerting region, so that, with increasing compression of the stamp, the contact region of the protective cover that comes into contact with the contact area during the inserting operation is pressed in a pressing region between the contact area and the stamp that increases in size from a first point of contact. As a result, inclusions of air between the contact area and the contact region of the protective cover that comes into contact with the contact area are forced out in the increasingly enlarging pressing region, extending out from the initial point of contact, so that on the one hand no air pockets remain and on the other hand no damage is caused to the protective cover by inclusions of air under pressure.

The protective cover preferably has a collar with which the protective cover is held over the stamp at a peripheral region of the applicator part running around the opening. The protective cover has a surround, which forms an inner space tapering conically from the collar to the contact region of the protective cover. In the case of a planar contact region of the protective cover, the surround and the contact region form a substantially frustoconical inner space. The shaping of the inner space of the protective cover makes it possible for the tip to fit in the inner space of the protective cover when it is inserted. The fact that the protective cover is held over the stamp by means of its collar makes it possible to prevent the contact region of the protective cover from adhering to the stamp, for example in an unsuitable position. If the tip with the applied protective cover is placed on an eye, the collar serves moreover for catching fluids, for example eye drops or lacrimal fluid, which run from the eye along the tip, and in this way prevent for example a grip that is connected to the tip from becoming slippery.

The contact region of the protective cover that comes into contact with the contact area is preferably formed as a membrane. The collar has an adhering region which faces the inner space and has a smooth surface, which is smoother than the surface of the side of the surround which faces the inner space. Forming the contact region of the protective cover that comes into contact with the contact area as a thin membrane has the advantage that the contact region of the protective cover adapts itself very well to the shape and surface of the contact area and influences measurements on the eye, in particular eye-pressure measurements, only to a negligible extent. The smooth surface of the flexible protective cover in the adhering region has an adherent, tacky effect. During insertion, the tip is pressed against the adhering region, the protective cover remains adhering to the inserted tip and can be pulled out together with the adhering protective cover from the depression of the applicator part through the opening of the applicator part.

In an implementational variant, the peripheral region has a groove which runs around the opening and is delimited from the opening by a bounding wall of the applicator part. The collar comprises an outer collar part running in the groove. The outer collar part has an outer inward collar region, which faces the opening, has a smooth surface and contacts the bounding wall. The protective cover is held in a defined position, for example centrally, in the depression by the outer collar part running in the groove. The smooth surface of the outer inward collar region has an adherent, tacky effect and causes the protective cover easily to adhere with the outer inward collar region to the bounding wall. As a result, the protective cover is prevented from unintentionally falling out of the depression of the applicator part, for example due to shaking movements or turning over of the applicator part.

In an implementational variant, the side of the surround facing the inner space has a number of channels which extend from the membrane to the collar. The channels permit the removal of air which is forced out of the region between the contact area and the contact region of the protective cover that comes into contact with the contact area. In particular, removal of the forced-out air is made possible when the tip is inserted in the protective cover and the surround is bearing against the tip.

The protective cover is preferably produced from an elastomer. The stamp is likewise produced from an elastomer and has a pressure-exerting region with a smooth surface. The contact region of the protective cover that comes into contact with the contact area is formed as a membrane with a smooth surface on both sides. The use of an elastomer for the protective cover on the one hand provides the extensibility and elasticity of the protective cover and on the other hand allows the adhesive effect of the surface of the protective cover to be controlled by structuring of the said surface. A roughened surface provided with an erosion structure has a small adhesive effect, while a polished, smooth surface has a great adhesive effect. The smooth surfaces of the pressure-exerting region of the stamp and of the membrane have the effect that even the smallest inclusions of air in the region between the contact area and the contact region of the protective cover that comes into contact with the contact area are forced out. The smooth surface of the membrane also has the effect that the protective cover adheres optimally with the membrane on the contact area of the tip.

Apart from the application system, the present invention also relates to a method for applying the flexible protective cover to an instrument part which has a tip tapering conically to a contact area which can be placed on an eye. According to the proposed method, the tip is inserted through an opening of an applicator part into the protective cover, which is arranged in a depression of the applicator part above a compressible stamp of the applicator part. The contact region of the protective cover that comes into contact with the contact area during insertion is pressed between the contact area and the stamp, so that air which is located between the contact region of the protective cover and the contact area is forced out of the contact region. Preferably, a stamp which has a convex pressure-exerting region is used and, during insertion, the contact region of the protective cover that comes into contact with the contact area is increasingly pressed between the contact area and the stamp, so that, with increasing compression of the stamp, the contact region of the protective cover that comes into contact with the contact area during the insertion is pressed in a pressing region between the contact area and the stamp that increases in size from a first point of contact. Preferably, the tip is inserted into an inner space of the protective cover tapering conically to the contact region of the protective cover until the tip is pressed against an adhering region with a smooth surface which is located in the region of a collar of the protective cover facing the inner space and is smoother than the surface of the remaining region of the protective cover facing the inner space. Then, the tip is pulled out with the protective cover adhering to the tip by means of the adhesive region from the depression of the applicator part through the opening.

The present invention finally also relates to an applicator part as described above in connection with the application system.

### BRIEF DESCRIPTION OF THE DRAWINGS

An implementation of the present invention is described below on the basis of an example. The example of the implementation is illustrated by the following accompanying figures:

FIG. 1 shows a cross section which schematically illustrates a flexible protective cover along the axis of symmetry.

FIG. 1a shows a view which schematically illustrates the flexible protective cover with indicated channels.

FIG. 1b shows a plan view which schematically illustrates the flexible protective cover with the channels.

FIG. 2 shows a cross section which schematically illustrates an applicator part.

FIG. 3 shows a cross section which schematically illustrates the applicator part with a protective cover received in it.

FIG. 4 shows a cross section which schematically illustrates the applicator part with a protective cover received in it and a tip of an ophthalmological instrument part inserted in the protective cover.

FIG. 5 shows a cross section which schematically illustrates the tip of the ophthalmological instrument part with a protective cover applied to it.

FIG. 6 shows a cross section which schematically illustrates a tip with a concave contact area and a protective cover applied to it.

FIG. 7a shows a cross section which schematically illustrates the first point of contact between the membrane and the stamp occurring during insertion.

FIG. 7b shows a cross section which schematically illustrates the pressing region between the membrane and the stamp that increases in size during the exertion of pressure.

### DETAILED DESCRIPTION OF THE INVENTION

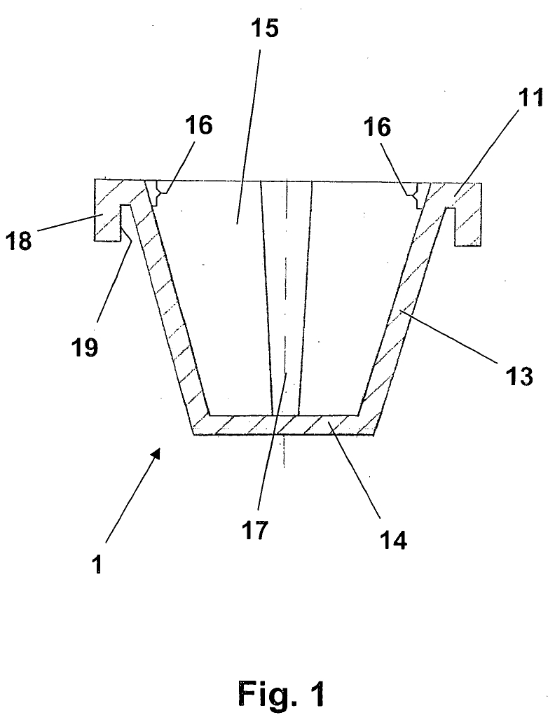

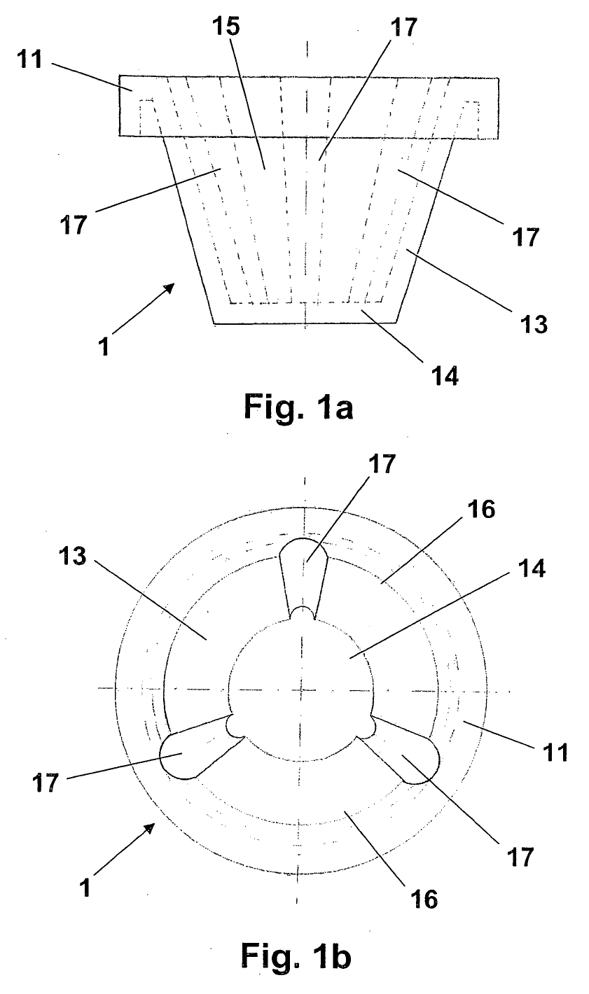

In FIGS. 1, 1a, 1b, 2, 3, 4, 5, 6, 7a and 7b, corresponding, identical components are designated by the same reference numerals.

In FIGS. 1, 1a, 1b, 2, 3, 4, 5, 6, 7a and 7b, the reference numeral 1 designates a flexible protective cover made of an elastomer, for example silicone, polyurethane, plasticized PVC or rubber. As can be seen from FIG. 1, the protective cover 1 is formed in a cup-shaped manner and has a circular base formed as a membrane 14, a peripheral surround 13, connected to the membrane 14, and a peripheral collar 11, connected to the surround 13. The collar 11 substantially has a U-shaped profile, which is formed in a round or angular manner. The collar 11 forms a periphery, which runs around the opening of the protective cover 1 and protrudes from the surround 13 in the direction facing away from the inner space 15. The diameter of the opening of the protective cover 1 is, for example, 9.8 mm. The membrane 14 has a highly polished, smooth surface, preferably on both sides. The membrane 14 has a constant thickness in the range from 40 μm to 50 μm, for example 45 μm. The diameter of the membrane 14 is, for example, 8 mm. The inner space 15 of the protective cover 1 that is formed by the membrane 14 and the surround 13 tapers conically from the collar 11 to the membrane 14 and, in the case of a planar membrane 14 is substantially frustoconical. As schematically represented in FIGS. 1a and 1b, the inner region of the surround 13 facing the inner space 15 has a number of channels 17, which respectively extend in a straight line from the membrane 14 to the collar 11. The channels 17 extend further in a straight line through at least part of the inner region of the collar 11 facing the inner space 15. Although it is not represented in FIGS. 1a and 1b, the surround 13 has, for example, eight symmetrically arranged channels 17. The surround 13 has, for example, a wall thickness which tapers continuously from 0.5 mm in the region of the collar 11 to 0.1 mm in the region adjacent to the membrane 14. The transition from the surround 13 to the membrane 14 is, for example, rounded, for example with an inner radius of 0.3 mm and an outer radius of 0.35 mm. The protective cover 1 has a height from the membrane 14 to its opening of, for example, 10 mm.

The inner region of the collar 11 facing the inner space 15 has a highly polished, smooth adhering region 16. The adhering region 16 has, for example, peripherally a width of 0.5 to 2 millimetres. The outer collar part 18 has a highly polished, smooth outer inward collar region 19 facing the inner space 15.

Apart from at the aforementioned locations, that is the two sides of the membrane 14, the adhering region 16 and the outer inward collar region 19, the protective cover 1 has a surface roughened by erosion structures.

The protective cover 1 is produced in one piece by means of hot runner mould. The protective cover 1 is produced in one piece by the injection-moulding process with subsequent forming. The surface finish of the protective cover 1 is determined by corresponding surface structures of the mould parts used of the hot runner mould. The corresponding surface regions of the mould parts for forming the membrane 14, the adhering region 16 and the outer inward collar region 19 are highly polished. In a first step, liquid elastic material is injected into the cavity between the inner mould part and the outer mould part. At the moment of injection, the inner mould part located inside the outer mould part is not in the nominal position of the membrane thickness but, for example, about 300 μm ahead of that. After the injection of the elastic material, when the cavity between the mould parts is filled, the inner mould part is brought into the nominal position, so that the highly polished surface regions are brought to within a distance of 50 μm to form a membrane thickness of 50 μm. The elastic material thereby forced out flows away. The connecting points produced as a result are mechanically removed after the curing of the elastic material.

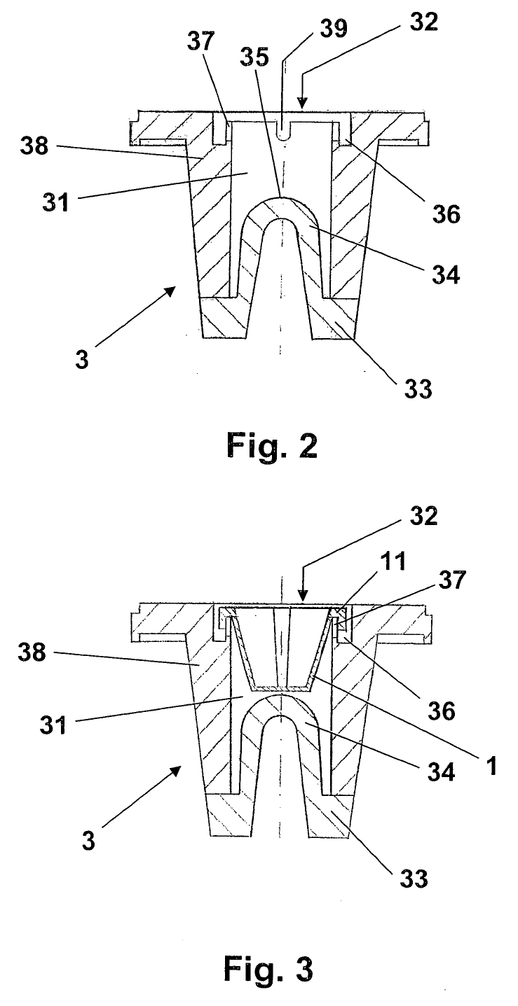

In FIGS. 2, 3 and 4, the reference numeral 3 relates to an applicator part. The applicator part 3 has a depression 31 with an opening 32 and a base part 33. The diameter of the opening 32 of the applicator part 3 is, for example, 10.9 mm. Attached to the base part 33 is a stamp 34 made of compressible material. The base part 33 and the stamp are, for example, produced as one part from an elastomer. The carrier part 38 of the applicator part 3 is, for example, produced from a non-deformable, hard plastic. The base part 33 with the stamp 34 attached to it is fastened to the carrier part, for example by means of a two-component injection-moulding process or by adhesive bonding. The stamp 34 has a convex pressure-exerting region 35 and is, for example, rounded. In order that the membrane 14 can be contacted as completely as possible by the stamp 34, the diameter of the stamp 34 is preferably at least as great as the diameter of the membrane 14. In the peripheral region running around the opening 32, the applicator part 3 also has a peripheral groove 36. The groove 36 is separated from the opening 32 by a bounding wall 37. The width of the groove 36 is, for example, 1.8 mm. The bounding wall 37 may also be provided with clearances 39. The wall thickness of the bounding wall 37 is, for example, 0.45 mm. The part of the peripheral region that lies on the side of the groove 36 that is opposite from the bounding wall 37 is formed such that, with respect to the base part 33, it is higher than the bounding wall 37, so that a removable covering film can be provided on the higher part of the peripheral region 34.

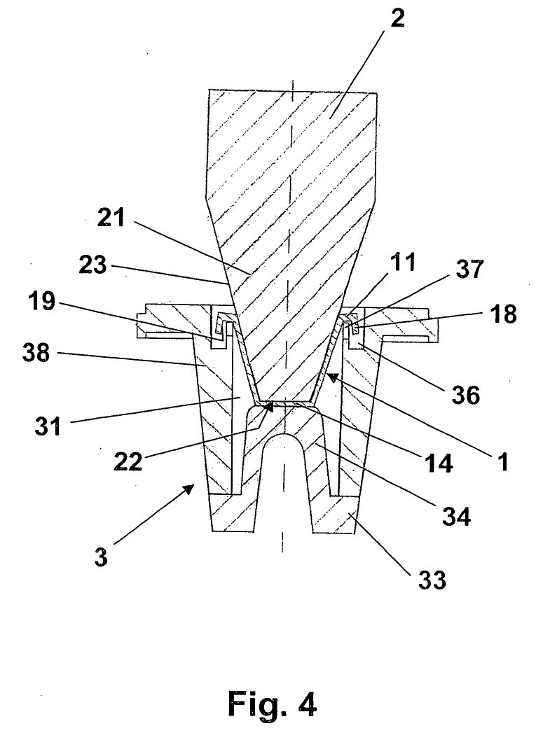

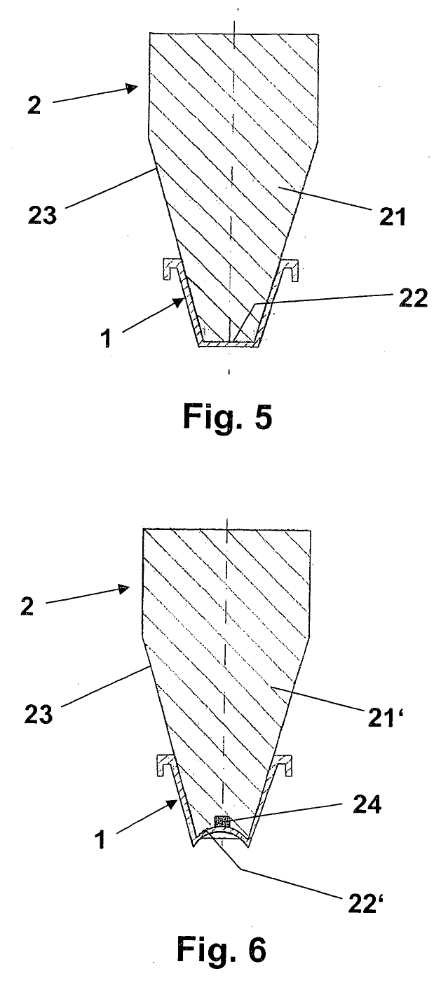

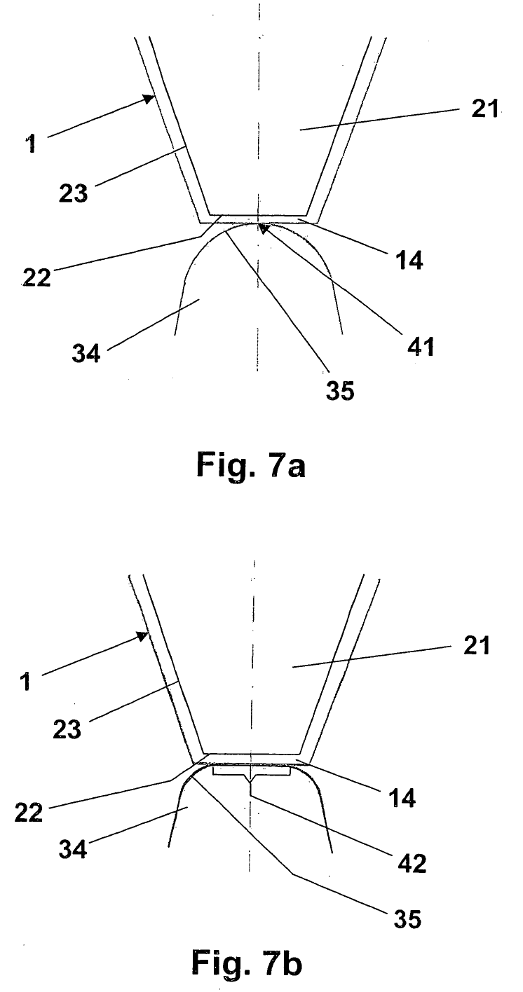

As can be seen from FIG. 3, the applicator part 3 is of such a form that it can receive the protective cover 1 in the depression 31. The application system made available to the user comprises an applicator part 3 and a sterile protective cover 1 received in it. The protective cover 1 is arranged in the depression 31 above the stamp 34 and is held over the stamp 34 without contact by means of the collar 11. The outer collar part 18 runs in the groove 36 and keeps the protective cover 1 central in the depression 31. The smooth outer inward collar region 19 is in touching contact with the side of the bounding wall 37 facing away from the opening 32 and so brings about a detachable adherence of the protective cover 1 to the applicator part 3. The aforementioned removable covering film allows the opening 32 to be closed and the sterile protective cover 1 provided in the depression 31 to be covered over and protected from contamination. To apply the protective cover 1 to the tip 21 of the ophthalmological instrument part 2, the covering film is removed from the applicator part 3 and the tip 21 is inserted through the opening 32 into the sterile protective cover 1 provided in the depression 31. During insertion, the side of the membrane 14 facing the inner space 15 comes into contact with the contact area 22 of the tip 21. By continuing the inserting movement and by exerting slight pressure, the membrane 14 is pressed onto the stamp 34 in the pressure-exerting region 35. As can be seen in FIG. 4, the stamp 34 is deformed by further exertion of pressure with the tip 21 and the membrane 14 is pressed between the contact area 22 and the pressure-exerting region 35. In FIGS. 7a and 7b, this pressure-exerting and pressing operation is illustrated by the example of a stamp 34 with a convex pressure-exerting region 35. During the inserting operation, the membrane 14 and the pressure-exerting region 35 of the stamp 34 initially touch at the point of contact 41 (FIG. 7a). By further pressing of the membrane 14 by means of the tip 21, the pressing region 42 (FIG. 7b) continuously increases in size from the first point of contact 41. This pressure-exerting operation with a progressively larger pressing region 42 has the effect that air which is trapped between the membrane 14 and the contact area is forced out of the pressing region 42 and carried away over the outer region 23 of the tip 21, in particular via the channels 17 described above. The applicator part 3 and the protective cover 1 are dimensioned in such a way that, in the state in which the membrane 14 is pressed between the contact area 22 and the pressure-exerting region 35, the outer region 23 of the tip 21 is pressed against the adhering region 16 of the collar 11 and at the same time the smooth outer inward collar region 19 is separated from the bounding wall 37 (FIG. 4). As a result, on the one hand the adherence of the collar 11 is detached from the bounding wall 37 and on the other hand an adherence of the adhering region 16 to the outer region 23 of the tip 21 is brought about. The protective cover 1 adheres both with the adhering region 16 to the outer region 23 of the tip 21 and with the membrane 14 to the contact area 22 of the tip 21. As represented in FIG. 5, the tip 21 with the protective cover 1 adhering to it can be pulled out from the depression 31 through the opening 32. Both the applicator part 3 and the protective cover 1 can be discarded or recycled after use.

At this point, it should be noted that the applicator system and application method described are not only suitable for planar contact areas 22 but can also be used for concave or convex contact areas. However, the radius of curvature of the pressure-exerting region 35 of the stamp 34 should be smaller than the radius of curvature of the contact area 22. FIG. 6 shows an example in which the protective cover 1 has been applied to a tip 21′ of a contour tonometer according to EP 1250884, which has a concave contact area 22′, into which a pressure sensor 24 with the same contour as the concave contact area 22′ is set.

Finally, it should be mentioned that the proposed application system and application method can be used even in the case of contact areas 22 which have surfaces with steps, offsets and/or gaps, if the latter may be spanned by a continuous curved shape without impairment of the measurement and in the stepped region air may be trapped between the protective cover 1 and the contact area 22.

The proposed application system and application method are suitable in particular for ophthalmological instrument parts such as measuring heads, for example tonometers, in particular contour tonometers with pressure sensors, and optical applicators, in particular pachymeters.

1. An application system, comprising:
a flexible protective cover for an ophthalmological instrument part, which has a tip tapering conically to a contact area to be placed on an eye, and
an applicator part for applying the protective cover to the tip,
wherein
the applicator part has a depression with an opening and a base part,
a stamp made of compressible material is attached to the base part and aligned by the base part in the direction of the opening, and
the protective cover is arranged above the stamp in the depression in such a way that it can be removed so that, to apply the protective cover, the tip can be inserted into the protective cover through the opening, a contact region of the protective cover that comes into contact with the contact area during the inserting operation being pressed between the contact area and the stamp and air which is located between the contact region of the protective cover and the contact area being forced out of the contact region.

2. The application system according to claim 1, wherein the stamp has a convex pressure-exerting region, so that, with increasing compression of the stamp, the contact region of the protective cover that comes into contact with the contact area during the inserting operation is pressed in a pressing region between the contact area and the stamp that increases in size from a first point of contact.

3. The application system according to claim 1, wherein the protective cover has a collar with which the protective cover is held over the stamp at a peripheral region of the applicator part running around the opening, and the protective cover has a surround, which forms an inner space tapering conically from the collar to the contact region of the protective cover.

4. The application system according to claim 3, wherein the contact region of the protective cover is formed as a membrane and the collar has an adhering region which faces the inner space and has a smooth surface, which is smoother than the surface of the side of the surround which faces the inner space.

5. The application system according to claim 3, wherein the peripheral region has a groove running around the opening, the groove is delimited from the opening by a bounding wall of the applicator part, the collar comprises an outer collar part running in the groove, and the outer collar part has an outer inward collar region, which faces the opening, has a smooth surface and contacts the bounding wall.

6. The application system according to claim 3, wherein the side of the surround facing the inner space has a number of channels which extend from the contact region to the collar.

7. The application system according to claim 1, wherein the protective cover is produced from an elastomer, the stamp is produced from an elastomer, the stamp has a pressure-exerting region with a smooth surface, and the contact region of the protective cover coming into contact with the contact area is formed as a membrane with a smooth surface on both sides.

8. A Method for applying a flexible protective cover to an ophthalmological instrument part which has a tip tapering conically to a contact area which can be placed on an eye, the method including:
insertion of the tip through an opening of an applicator part into the protective cover, which is arranged in a depression of the applicator part above a compressible stamp of the applicator part, pressing of a contact region of the protective cover that comes into contact with the contact area during insertion between the contact area and the stamp, so that air which is located between the contact region of the protective cover and the contact area is forced out of the contact region.

9. The method according to claim 8, further including use of a stamp, which has a convex pressure-exerting region, and increasing pressing of the contact region of the protective cover that comes into contact with the contact area during the insertion between the contact area and the stamp, so that, with increasing compression of the stamp, the contact region of the protective cover that comes into contact with the contact area is pressed in a pressing region between the contact area and the stamp that increases in size from a first point of contact.

10. The method according to claim 8, further including insertion of the tip into an inner space of the protective cover tapering conically to the contact area until the tip is pressed against an adhering region with a smooth surface, which adhering region is located in a region of a collar of the protective cover facing the inner space and is smoother than the surface of the remaining region of the protective cover facing the inner space, the protective cover being held over the compressible stamp by the collar at a peripheral region of the applicator part running around the opening, and pulling out of the tip with the protective cover adhering to the tip by means of the adhesive region from the depression of the applicator part through the opening.

11. An applicator part for applying a flexible protective cover to a tip of an ophthalmological instrument part tapering conically to a contact area which can be placed on an eye,
wherein
the applicator part has a depression with an opening and a base part for receiving the protective cover,
a stamp made of compressible material is attached to the base part and aligned by the base part in the direction of the opening, and,
for applying the protective cover, the tip can be inserted into the protective cover provided in the depression through the opening in such a way that a contact region of the protective cover provided in the depression that comes into contact with the contact area during the inserting operation is pressed between the contact area and the stamp and air which is located between the contact region of the protective cover and the contact area is forced out of the contact region.

12. The applicator part according to claim 11, wherein the stamp has a convex pressure-exerting region, so that, with increasing compression of the stamp, the contact region of the protective cover provided in the depression that comes into contact with the contact area during the inserting operation is pressed in a pressing region between the contact area and the stamp that increases in size from a first point of contact.
